(19) United States
(12) Patent Application Publication
(10) Pub. No.: US 2026/0233355 A1
(43) Pub. Date: Aug. 13, 2026

(54) SYSTEM AND METHOD FOR CHEMICAL MECHANICAL POLISHING

(71) Applicant: Taiwan Semiconductor Manufacturing Company, Ltd., Hsinchu (TW)

(72) Inventors: Chen-Hao WU, Hsinchu (TW); Yi Hsing Yu, Hsinchu city (TW); Chia Jou LIU, Taichung City (TW); Huang-Lin CHAO, Hsinchu City (TW); Pinyen LIN, Rochester, NY (US)

(73) Assignee: Taiwan Semiconductor Manufacturing Company, Ltd., Hsinchu (TW)

(21) Appl. No.: 19/048,577

(22) Filed: Feb. 7, 2025

(51) Int. Cl. B24B 37/04; B24B 57/02; C09G 1/02; H01L 21/3105

(52) U.S. Cl. CPC B24B 37/044; B24B 57/02; C09G 1/02; H10P 95/062

(57) ABSTRACT

The present disclosure describes a system and a method for a chemical mechanical polishing (CMP) process on a substrate. The CMP process planarizes a portion of a material layer on the substrate and selectively polishes another portion of the material layer within a predetermined distance from a stop layer. The system includes a polishing pad on a rotating platen and a dispenser configured to dispense an abrasive solution and an additive solution onto the polishing pad. The abrasive solution and the additive solution blend on the polishing pad to form a slurry, which is used to perform the CMP process on the substrate.

### BACKGROUND

Polishing semiconductor wafers with a chemical mechanical planarization (CMP) system requires slurry preparation involving diluting and blending an abrasive component with an additive component. The additive component and the abrasive component of the CMP slurry can be blended at various stages in the CMP process. The stage at which the slurry is prepared can affect the functionality and quality of the slurry.

### BRIEF DESCRIPTION OF THE DRAWINGS

Aspects of the present disclosure are best understood from the following detailed description when read with the accompanying figures. It is noted that, in accordance with common practice in the industry, various features are not drawn to scale. In fact, the dimensions of the various features may be arbitrarily increased or reduced for clarity of discussion.

FIG. 1 illustrates a schematic of a polishing system, according to some embodiments.

FIG. 2 illustrates variation of pH of three different slurries, according to some embodiments.

FIG. 3 illustrates particle size distribution of abrasive component of three different slurries, according to some embodiments.

FIGS. 4A-4D illustrates a cross-sectional view of polishing tools used for performing chemical mechanical polishing (CMP) processes, according to some embodiments.

FIG. 5 illustrates a method of operating a CMP system, according to some embodiments.

FIGS. 6A-6E illustrate cross-sectional views of a CMP system implementing a method of operating the CMP system, according to some embodiments.

FIG. 7 illustrates step height data collected by a detection device, according to some embodiments.

FIG. 8A illustrates a method of operating a polishing system to perform a CMP process on a substrate with an oxide layer, according to some embodiments.

FIGS. 8B-8D illustrate cross-sectional view of a partially-fabricated substrate undergoing a CMP process, according to some embodiments.

FIG. 9 illustrates a variation of oxide removal rate versus pressure, according to some embodiments.

FIG. 10A illustrates a current, voltage, or platen torque signal collected by a detection device, according to some embodiments.

FIGS. 10B and 10C illustrate oxide loss data measured during a CMP process, according to some embodiments.

FIG. 11A illustrates a method operating a polishing system to perform a CMP process on a substrate with silicon nitride layer, according to some embodiments.

FIGS. 11B-11D illustrate cross-sectional view of a partially-fabricated substrate undergoing a CMP process, according to some embodiments.

FIG. 12A illustrates a current, voltage, or platen torque signal collected by a detection device, according to some embodiments.

FIGS. 12B and 12C illustrate silicon nitride loss data measured during a CMP process, according to some embodiments.

FIG. 13 illustrates a variation in removal rate versus abrasive component concentration, according to some embodiments.

FIG. 14 illustrates a high-level block diagram of a computer system, according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed that are between the first and second features, such that the first and second features are not in direct contact.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “about” as used herein indicates the value of a given quantity that can vary based on a particular technology node associated with the subject semiconductor device. In some embodiments, based on the particular technology node, the term “about” can indicate a value of a given quantity that varies within, for example, 5-30% of the value (e.g., ±5%, ±10%, ±20%, or ±30% of the value).

Chemical mechanical planarization (CMP) (also referred to herein as “chemical mechanical polishing” or “polishing”) is a planarization technique that can be used to planarize a substrate's surface by a relative motion between a substrate and a polishing pad in the presence of a slurry. A downward pressure can be applied to the substrate during the CMP process. In the CMP system, the substrate (also referred to herein as “wafer”) is positioned face down on a wafer holder, or substrate carrier, and held against a polishing pad positioned on a flat surface (also referred to herein as a “platen”). A slurry is dispensed onto the polishing pad. The polisher can use either a rotary or orbital motion during the polishing process. The CMP process achieves substrate planarity by removing elevated features relative to recessed features on the substrate's surface.

A CMP process can have several stages, such as removal of an initial step height of a material layer (also referred to herein as “planarization operation”) and a selective polishing operation for the CMP process to stop at another material layer. These stages can require different slurry compositions to avoid over-polishing or under-polishing different areas on the substrate. The slurry is a mixture of an abrasive solution and an additive solution. The abrasive solution of the slurry removes a material layer from the substrate using mechanical abrasion. The abrasive solution plays a dominant role in removing a bulk portion of the material layer; or in other words, works to physically planarize the substrate's surface due to a physical grinding process occurring between the abrasive solution and the substrate. On the other hand, the additive solution of the slurry chemically etches material from the substrate's surface by a chemical reaction between additive solution and the material layer on the substrate's surface. Therefore, the additive solution forming the slurry enables the CMP process to selectively stop at another material layer on the wafer surface (also referred to herein as “stop layer”).

The slurry can be prepared in a mixing tank prior to being dispensed on the wafer during a CMP process. Slurry preparation can include (a) diluting an abrasive component in de-ionized (DI) water to form an abrasive solution, (b) diluting an additive component in the DI water to form an additive solution, and (c) mixing the abrasive solution and the additive solution to form the slurry. Using a pre-mixed slurry can pose challenges in achieving an optimum material removal rate. The abrasive component of the slurry includes nano-sized abrasive particles. A first challenge resulting from using a pre-mixed slurry is that, over time, the suspended nano-sized particles suspended in the slurry solution along with the additive component can agglomerate to form larger particles. Agglomeration affects (a) a pH of the slurry and (b) a removal rate of the material layer due to a larger particle size. A slurry with a pH between about 4.0 and about 5.0 can provide an optimum removal rate. An abrasive solution with a pH greater than 5 can be unstable. When the abrasive solution is mixed with the additive solution to form the slurry, the pH of the slurry can increase. An increase in pH can result in a decrease in H⁺ ions in the slurry, which can increase a zeta potential of the slurry. An increase in zeta potential can reduce a repulsion effect between the cerium hydroxide (Ce(OH)₄) particles, which can promote agglomeration. Therefore, increased pH can cause the abrasive component (Ce(OH)₄) to agglomerate. The agglomeration can result in larger abrasive component particles which can reduce an overall surface area of the abrasive component in contact with the surface of the wafer being polished. This can reduce the polishing rate of the CMP process.

A second challenge to using a pre-mixed slurry is that a composition of the slurry remains fixed for all stages of the CMP process. For example, the slurry used for planarizing a bulk of the material layer will also be used to polish areas of the wafer that require more material selectivity. This can lead to under polishing material layers that require a more abrasive CMP process and over-polishing of material layers that require a more material layer selective CMP process. Therefore, a fixed slurry composition does not provide flexibility to optimize performance of a CMP process for polishing material layers at various stages of the CMP process.

The present disclosure provides a CMP system and method in which the slurry performance—which depends on a mixing ratio of the abrasive solution and the additive solution—can be optimized by controlling flow rates of the abrasive and additive solutions. In the disclosed CMP system and method, the abrasive solution and the additive solution are dispensed on the polishing pad through two separate nozzles and mixed on the polishing pad to form the slurry. The concentration or mixing ratio of the abrasive solution and the additive solution can be adapted while a total flow rate remains substantially constant. Further, since the abrasive solution and the additive solution are not pre-mixed to form the slurry, the agglomeration of abrasive particles can be suppressed to prevent formation of larger abrasive particles. Smaller abrasive component particles provide a higher polish rate due to a larger contact area between abrasive particles and the substrate. Additionally, not mixing the abrasive solution and additive solution can prevent (a) a temperature change of slurries with different mixing ratios and (b) a volume change of the slurry due to a temperature change during the abrasive solution and additive solution mixing process. A benefit of the present disclosure, among others, is a CMP system and method that provides an optimized CMP process using a single platen and a single abrasive solution to CMP different dielectric layers. An optimized CMP process refers to a CMP process that can be modified to be effective for (a) a planarization operation that is a physically abrasive polishing process and (b) a selective polishing operation that is a chemical process in which the additive solution (e.g., a chemically-reactive component) selectively reacts with the material layer and the abrasive component mechanically removes the material layer. During the planarization operation, the material layer can be predominantly removed by physical abrasion. On the other hand, during the selective polishing operation, the material layer can be predominantly removed by a chemical reaction.

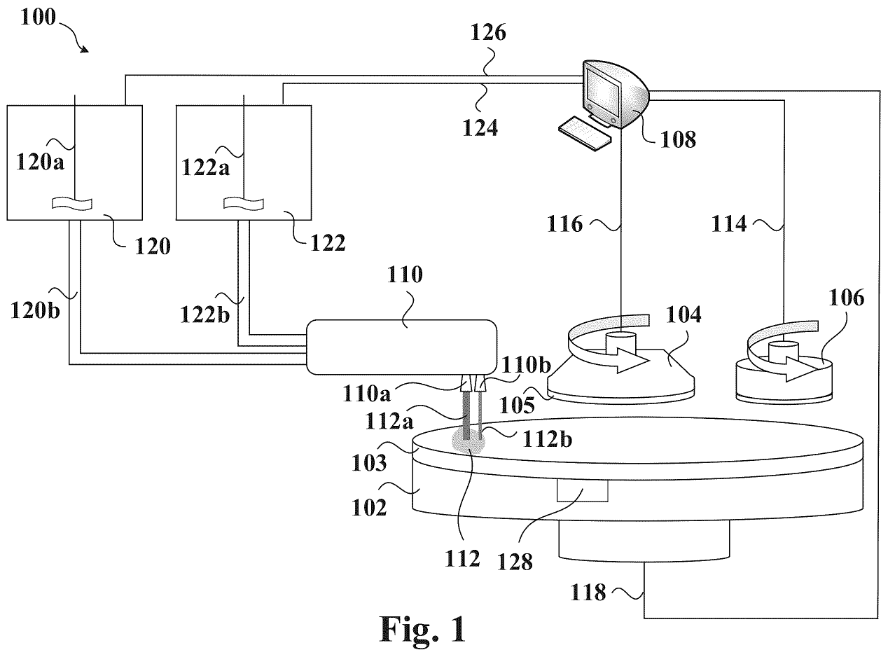

FIG. 1 is a schematic of a CMP system 100, in accordance with some embodiments of the present disclosure. As illustrated in FIG. 1, CMP system 100 can include a polishing pad 103 which is loaded on a rotating platen (e.g., a rotating table) 102. CMP system 100 can also include a rotating substrate carrier 104 that holds substrate 105, a rotating conditioning wheel (or “disk”) 106, a dispenser 110 fluidly connected to an abrasive solution mixing tank 120 and an additive solution mixing tank 122. CMP system 100 also includes a computer system 108, where various components of the CMP system can be configured to communicate with computer system 108 via communication links. In some embodiments, rotating platen 102 can communicate with computer system 108 through communication link 118. Disk 106 and substrate carrier 104 can communicate with computer system 108 through communication links 114 and 116, respectively. Similarly, in some embodiments, abrasive solution mixing tank 120 and additive solution mixing tank 122 can communicate with computer system 108 through communication links 126 and 124, respectively. For illustration purposes, FIG. 1 includes selected portions of CMP system 100 and other portions (not shown) may be included, such as control units, transfer devices, pumps, and drains. In some embodiments, communication links 114, 116, 118, 124, and 126 can be a wired or wireless links.

In some embodiments, CMP system 100 can include separate mixing tanks for the abrasive solution and the additive solution that form the slurry. For example, as described with reference to FIG. 1, CMP system 100 includes abrasive solution mixing tank 120 with first agitator 120a. Abrasive components including nano-sized abrasive particles can be diluted in the DI water in abrasive solution mixing tank 120. Feeder 120b can supply the abrasive solution to dispenser 110. The system also includes additive solution mixing tank 122 with second agitator 122a. Additive components—which can be chemically reactive species—can be diluted in the DI water in additive solution mixing tank 122. Feeder 122b can supply the additive solution to dispenser 110. Agitators 120a and 122a can include a fan in abrasive solution 112a and additive solution 112b and a bearing supporting the fan. The bearing can be coupled to a motion mechanism (not shown), such as a pump or a motor, to rotate the fan. In some embodiments, agitators 120a and 122a can be ultrasonic devices or oscillator devices.

In some embodiments, the dispenser can include separate nozzles for dispensing the abrasive solution and the additive solution onto the wafer. For example, as described with reference to FIG. 1, dispenser 110 can include nozzle 110a for dispensing abrasive solution 112a and nozzle 110b for dispensing additive solution 112b. Nozzles 110a and 110b can be connected to flow controllers (not shown) that can control the flow rate of abrasive solution 112a and additive solution 112b flowing through nozzles 110a and 110b, respectively. Abrasive solution 112a and additive solution 112b can blend on polishing pad 103 to form the slurry. The flow controllers and the flow rate of the abrasive solution and the additive solution can be controlled by computer system 108.

In some embodiments, the abrasive component of abrasive solution 112a can be one or more of silicon dioxide (SiO₂), aluminum oxide (Al₂O₃), cerium dioxide (CeO₂), cerium hydroxide (Ce(OH)₄), carbon (C), silicon carbide (SiC), or titanium dioxide (TiO₂). Depending on the substrate polishing application, the one or more abrasives components can include particles of SiO₂, CeO₂, Al₂O₃, zirconium oxide (ZrO₂), TiO₂, iron oxide (Fe₂O₃), zinc oxide (ZnO), or any other suitable material.

Polishing pad 103 attaches to a top surface of rotating platen 102. Polishing pad 103 can be made for example, from polyurethane due to polyurethane's mechanical characteristics and porosity. Further, polishing pad 103 can include small perforations to help transport the slurry along the wafer's surface and promote uniform polishing. Polishing pad 103 also removes the reacted products away from the wafer surface. As polishing pad 103 polishes more wafers, the polishing pad's surface becomes flat and smooth, causing a condition referred to as “glazing.” Glazed pads cannot hold the polishing slurry—which significantly decreases the polishing rate.

Substrate 105 (also referred to herein as “wafer 105”) to be polished is mounted face-down at the bottom of substrate carrier 104 so that the substrate's top surface contacts the top surface of polishing pad 103. Substrate carrier 104 rotates substrate 105 and exerts pressure (e.g., a downforce) on it so that substrate 105 is pressed against rotating polishing pad 103. Abrasive solution 112a and additive solution 112b can be dispensed on the polishing pad's surface, where they blend to form slurry. Based on a mixing ratio or respective flow rates of abrasive solution 112a and additive solution 112b, the slurry formed on the polishing pad can be more mechanically abrading or a more chemically reactive. Chemical reactions and mechanical abrasion among the slurry, substrate 105, and polishing pad 103 can result in material removal from the top surface of substrate 105. At the same time, conditioning disk 106 can agitate the top surface of polishing pad 103 to restore its roughness. However, this is not limiting and conditioning disk 106 can condition polishing pad 103 after substrate 105 has been polished and removed from CMP system 100.

Polishing pads 103 require regular conditioning to retard the effects of glazing. The purpose of conditioning is to remove old slurry particles and abraded particles from the polishing pad to extend the polishing pad's lifetime and provide consistent polishing performance throughout its lifetime. Polishing pads can be conditioned with mechanical abrasion or a deionized (DI) water jet spray that can agitate (activate) the pad's surface and increase its roughness. An alternative approach to activate the pad's surface is to use conditioning disk 106 featuring a bottom diamond surface that contacts polishing pad 103 while it rotates.

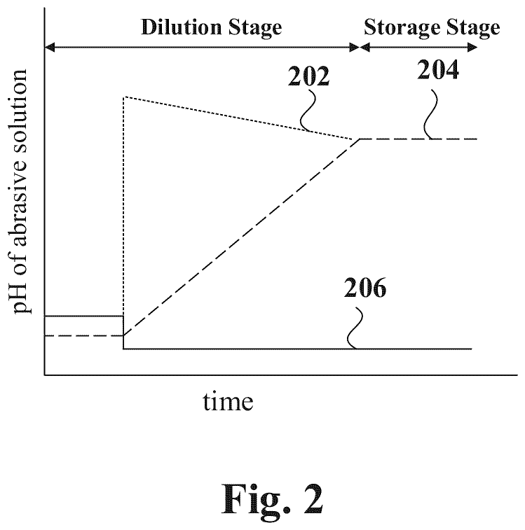

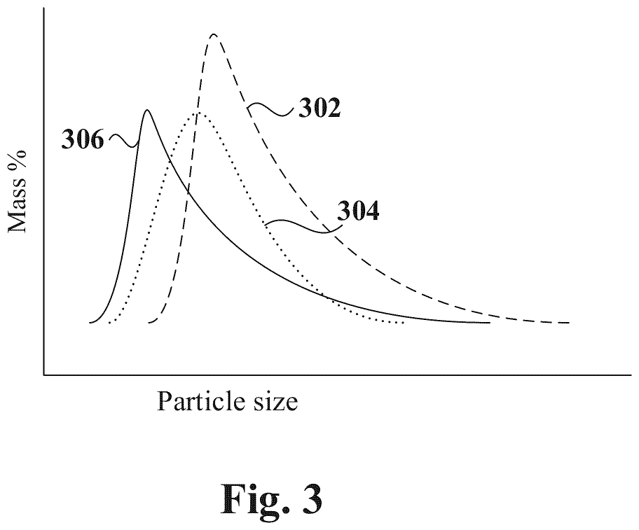

The pH of the pre-mixed slurry solution can change over time, which can affect the polishing rate or material removal rate. For example, FIG. 2 shows variation of pH of first, second, and third slurries over time. Curve 202 represents pH of a first slurry solution prepared by (a) a first operation involving blending an additive component with DI water to form an additive solution with DI water with a certain pH (e.g., of about 7.9), and (b) a second operation involving adding a 1% abrasive solution with a another pH (e.g., of about 4.4) to the additive solution to form the first slurry with an additive component, DI water, and an abrasive component in the ratio 2:17:1. As an example, the abrasive component can be cerium hydroxide Ce(OH)₄. As shown by curve 202, the pH of the first slurry can change rapidly over time during a dilution stage and can, for example, abruptly increase to about 7.8 at a certain time. During the storage stage, the pH of the first slurry remains substantially constant, as shown in FIG. 2. FIG. 3 shows variation of mass percentage of abrasive component (particle size distribution) of a slurry with an increase in particle size due to agglomeration. The pH of the first slurry increases due to a larger number of Ce(OH)₄ particles agglomerating to form large clusters of Ce(OH)₄ particles as shown by curve 302 in FIG. 3. As explained above, the increase in pH of the slurry can be accompanied with a reduction in zeta potential. The first slurry with a pH of about 6.7 can, for example, have a zeta potential of about 21 mV. The low zeta potential can promote agglomeration.

Curve 204 in FIG. 2 represents a second slurry prepared by (a) a first operation involving blending an abrasive component (e.g., with a weight of about 0.06%) with DI water to form an abrasive solution with a certain pH (e.g., of about 4.1), and (b) a second operation involving adding an additive component with another pH (e.g., of about 8.0) to the abrasive solution to form the second slurry with an abrasive component, DI water and an additive component in the ratio 1:17:2. As shown by curve 204, the pH of this second slurry can change smoothly over time during the dilution stage and can gradually increase, for example, to about 7.8. During the storage stage, the pH of the first slurry remains substantially constant, as shown in FIG. 2. Similar to the first slurry, the pH of the second slurry can also increase over time due to a large number of Ce(OH)₄ particles agglomerating to form large clusters of Ce(OH)₄ particles as shown by curve 304 in FIG. 3. Based on the above, the pH of the first and second slurries increase over time to, for example, about 7.8, which is outside a pH range required for optimum slurry performance and removal rate.

The present disclosure discloses the third slurry that remains stable over time and does not agglomerate over time as the first and second slurries described above. Curve 206 in FIG. 2 represents the third slurry prepared by (a) blending an abrasive component (e.g., with a weight of about 0.1%) in DI water to form an abrasive solution with a certain pH (e.g., of about 4.2), (b) blending an additive component in DI water to form an additive solution with another pH (e.g., of about 8), and (c) mixing the abrasive solution and the additive solution on the polishing pad to form the third slurry. As shown by curve 206, during the dilution and storage stage, the pH of the third slurry can remain stable between about 4.0 and about 5.0, according to some embodiments. Compared to the first and second slurries, the agglomeration of abrasive component particles, such as Ce(OH)₄, in the third slurry solution is the least, as shown by curve 306 in FIG. 3. Since the pH of the third slurry is stable, the third slurry with a pH of about 4.0 can, for example, have a zeta potential of about 68 mV. In some embodiments, the agglomeration is suppressed in the third slurry because the abrasive solution and additive solution are mixed on the polishing pad. Therefore, the abrasive component in the third slurry can have a larger surface area than the abrasive component in the first and second slurries that can contact and polish the wafer.

Additionally, agglomeration of abrasive particles can also affect removal rate due to a change in size of abrasive particles and the number of particles in the slurry. Abrasive particles smaller in size can have a larger surface area that contacts and grinds the wafer surface producing a higher removal rate. On the other hand, a smaller number of large agglomerates of the abrasive particles provide a smaller surface area that grinds the wafer surface. Therefore, the material removal rate of the pre-mixed slurry can reduce over time. The agglomerates can scratch dielectric layers and metal layer resulting in higher wafer level defectivity. This can affect wafer-to-wafer (WtW) and lot-to-lot (LtL) polishing repeatability (e.g., consistent polish rate and consistent polish uniformity across the wafer and across a die). In some embodiments, the first and second slurries described above can agglomerate over time. Consequently, the removal rate for the first and second slurries can be lower than the removal rate for the third slurry. In some embodiments, a removal rate of an oxide material layer (a) using the first slurry with a flow rate of about 250 ml/min can be about 790 Å/min, (b) using the second slurry with a flow rate of about 250 ml/min can be about 887 Å/min, and (c) using the third slurry with the abrasive solution flow rate of about 125 ml/min and the additive solution flow rate of about 125 ml/min can be about 1061 Å/min. Based on the above, the oxide material layer removal rate using the third slurry can be about 34% higher than the removal rate using the first slurry. In some embodiments, a removal rate of an SiN material layer (a) using the first slurry with a flow rate of about 250 ml/min can be about 345 Å/min, (b) using the second slurry with a flow rate of about 250 ml/min can be about 355 Å/min, and (c) using the third slurry with the abrasive solution flow rate of about 125 ml/min and the additive solution flow rate of about 125 ml/min can be about 457 Å/min. Based on the above, the SiN material layer removal rate using the third slurry can be about 32% higher than the removal rate using the first slurry.

The size of abrasive particles can also affect the material layer removal rate across the wafer radius. For example, smaller abrasive particles can contribute to a lower material layer removal rate on the wafer edge (e.g., about 146 mm to about 150 mm from a center of the wafer) compared to the wafer center. In other words, larger abrasive particles can contribute to a higher material layer removal rate on the wafer edge compared to the wafer center. Based on the above, the first and second slurries can have a higher material layer removal rate on the wafer edge compared to the wafer center. Alternatively, the third slurry has a lower material layer removal rate on the wafer edge compared to the wafer center, due to suppressed agglomeration of the abrasive component.

In some embodiments, the abrasive component can include one or more of cerium oxide (CeO₂), silica (SiO₂), and cerium hydroxide (Ce(OH)₄). In some embodiments, imidazole (C₃H₄N₂), which is a catalyst, can be added during preparation of a Ce(OH)₄ based abrasive solution. In some embodiments, the additive solution can include additive components, such as acetic acid and ammonium acetate. In some embodiments, water-soluble polymers, such as polyvinyl alcohol (PVA), polyethylenimine (PEI), polyvinylpyrrolidone (PVP), peroxyacetic acid (PAA), and polyethylene glycol (PEG), can be added to the additive solution.

In some embodiments, CMP system 100 can be configured to polish substrates with surfaces that include different types of materials, such as silicon, germanium, arsenic, nitrogen, oxygen, and metals.

Referring to FIG. 1, CMP system 100 can also include a detection device 128 configured to measure the polishing characteristic associated with a polishing process. The polishing characteristic can include one or more of a polishing rate, a surface roughness, a surface uniformity, a surface dishing, material composition of an exposed material layer, and a surface defect density associated with substrate 105. In some embodiments, detection device 128 can be configured to measure the polishing characteristic during the polishing process. Detection device 128 can be an in-situ monitoring apparatus attached to or embedded in platen 102. In some embodiments, detection device 128 can be attached to substrate carrier 104. Detection device 128 can include an optical interferometer or an optical reflectometer to generate an optical signal directed towards substrate 105 and detect a respective optical reflectance signal associated with a thickness or a surface roughness of a film (e.g. a copper layer) on substrate 105. In some embodiments, detection device 128 can include an electrode structure configured to detect an electrical current or electrical voltage associated with the film thickness or a material composition of the exposed layer on substrate 105. In some embodiments, detection device 128 can be an apparatus configured to measure one or more of a mechanic displacement, a force or torque, a vibration signal, an acoustic signal, a thermal signal, and a radioactivity signal associated with the polishing characteristic.

In some embodiments, computer system 108 can be configured to store the one or more instructions for the polishing process, where the one or more instructions can include one or more parameters of the polishing process, such as a supply rate of abrasive solution 112a and additive solution 112b. Computer system 108 can be further configured to send the one or more instructions to components of CMP system 100 via communication links 114, 116, 118, 124, and 126. In some embodiments, computer system 108 can receive the detected polishing characteristic measured on wafer 105 and can be configured to generate an adjustment of the one or more parameters of the polishing process based on the detected polishing characteristic. In some embodiments, the adjustment can be generated based on another polishing characteristic detected by another ex-situ independent detection apparatus, such as stand-alone Atomic Force Microscopy (AFM). In some embodiments, the adjustment can be in flow rates of abrasive solution 112a and additive solution 112b based on a polishing characteristic, such as a surface profile or material composition of an exposed material layer on substrate 105.

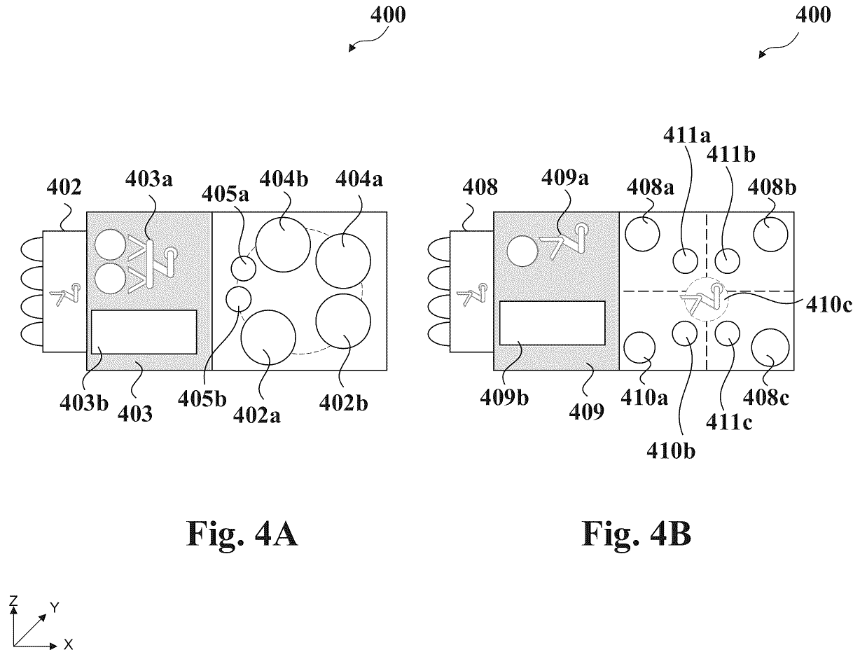

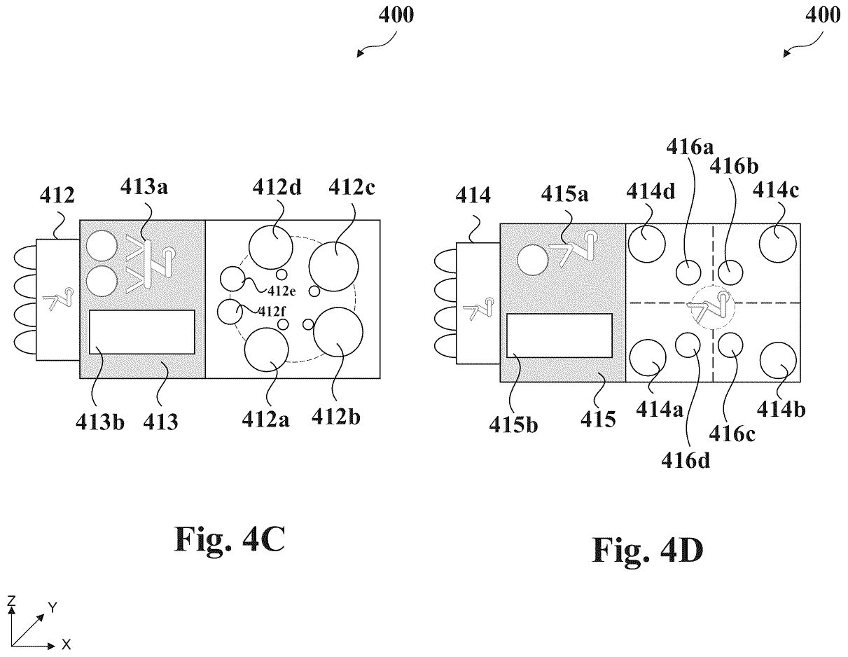

FIGS. 4A, 4B, 4C, and 4D illustrate different configurations of a CMP tool 400. CMP tool 400 can have multiple platens for performing pre-CMP processes, CMP processes, and post-CMP processes. A pre-CMP process can be a pre-clean process to remove particles and/or contaminants from a wafer surface before undergoing a CMP process. Particles and contaminants can get trapped between the wafer and the polishing pad to scratch the wafer surface. The pre-clean process can be a wet clean, such as a DI water rinse, argon aerosol clean, or any other suitable cleaning process. Post CMP processes can include a CMP buffing process, in which slurry particles left on the wafer surface can be removed by brush scrubbing. Brush scrubbing can include, for example, cleaning the polished wafer surface with soft polyvinyl alcohol brushes (PVA) brushes. After brush scrubbing, the polished wafer can be rinsed with isopropyl alcohol (IPA) and dried.

As described with reference to FIG. 4A, CMP tool 400 can include four platens 402a, 402b, 404a, and 404b. Wafers can be loaded onto CMP tool 400 using load ports 402. A robotic arm can transfer the wafers from load port 402 to a processing chamber 403, from where robot 403a can transfer the wafers to two load/unload units 405a and 405b. Polishing heads for each of platens 402a and 402b can load the wafers onto platens 402a and 402b. Platens 402a and 402b can be configured to perform a CMP process on the wafers. Platens 402a and 402b can be part of a CMP system similar to CMP system 100 illustrated in FIG. 1. For example, platens 402a and 402b can each have a dispenser 110 fluidly connected to abrasive solution tank 120 and additive solution tank 122, polishing pad 103, and substrate carrier 104 communicatively connected to computer system 108. Platens 404a and 404b can be configured to perform post CMP processes on the wafers polished on platens 402a and 402b. Post CMP processes performed on platens 404a and 404b can include polishing using silica slurry and/or a buff clean. After the post CMP process, the wafers can be transferred back to processing chamber 403 by robot 403a. Processing chamber 403 on CMP tool 400 shown in FIG. 4A can include clean module 403b, which can perform pre-and post-polishing operations. Pre-polishing operations can include, for example, a pre-clean. Post CMP processes can include, for example, the brush roller clean and/or the IPA rinse and dry.

As described with reference to FIG. 4B, CMP tool 400 can include four platens 408a, 408b, 408c, and 410a. Wafers can be loaded onto CMP tool 400 using load ports 408. A robotic arm can transfer the wafers from load port 408 to a processing chamber 409, from where robot 409a can transfer the wafers to robot 410c. Robot 410c can load the wafers onto load/unload units 411a, 411b, and 411c. Polishing heads for each of platens 408a, 408b, and 408c can transfer the wafers to platens 408a, 408b, and 408c, respectively. Each of platens 408a, 408b, and 408c can have up to two polishing heads (not shown). Platens 408a, 408b, and 408c can be configured to perform a CMP process on the wafers. Platens 408a, 408b, and 408c can be part of a CMP system similar to CMP system 100 illustrated in FIG. 1. For example, platens 408a, 408b, and 408c can each have dispenser 110 fluidly connected to abrasive solution tank 120 and additive solution tank 122, polishing pad 103, and substrate carrier 104 communicatively connected to computer system 108. Platen 410a can be configured to perform post CMP processes on the wafers. Post CMP, the wafer can be transferred to load/unload unit 410b. A polishing head of platen 410a can transfer the wafer from load/unload unit 410b to platen 410 for performing the post CMP process. Platen 410a can have up to two polishing heads (not shown). After the post CMP process, the wafers can be transferred back to processing chamber 409 by the carrier 409a. Processing chamber 409 on CMP tool 400 shown in FIG. 4B can include clean module 409b, which can perform pre-and post-polishing operations. Pre-polishing operations can include, for example, a pre-clean. Post CMP processes can include, for example, the brush roller clean and/or the IPA rinse and dry.

As described with reference to FIG. 4C, CMP tool 400 can include four platens 412a, 412b, 412c, and 412d. Wafers can be loaded onto CMP tool 400 using load ports 412. A robotic arm can transfer the wafers from load port 412 to a processing chamber 413, from where robot 413a can load the wafers onto load/unload units 412e and 412f. Polishing head for platens 412a, 412b, 412c and 412d can transfer the wafers from load/unload units 412e and 412f to platens 412a, 412b, 412c and 412d. Platens 412a, 412b, 412c, and 412d can be configured to perform a CMP process on the wafers. Platens 412a, 412b, 412c, and 412d can be part of a CMP system similar to CMP system 100 illustrated in FIG. 1. For example, platens 412a, 412b, 412c and 412d can each have dispenser 110 fluidly connected to abrasive solution tank 120 and additive solution tank 122, polishing pad 103, and substrate carrier 104 communicatively connected to computer system 108. After the CMP process, the wafers can be transferred back to processing chamber 413 by robot 413a. Processing chamber 413 on CMP tool 400 shown in FIG. 4C can include clean module 413b, which can perform pre-polishing and post-polishing operations. Pre-polishing operations can include, for example, a pre-clean. Post CMP processes can include, for example, a brush roller clean and/or IPA rinse and dry.

As described with reference to FIG. 4D, CMP tool 400 can include four platens 414a, 414b, 414c, and 414d. Wafers can be loaded onto CMP tool 400 using load ports 414. A robotic arm can transfer the wafers from load port 414 to a processing chamber 415, from where robot 415a can load the wafers onto load/unload units 416a, 416b, 416c, and 416d. Polishing heads for platens 414a, 414b, 414c and 414d can transfer the wafers to platens 414a, 414b, 414c and 414d, respectively. Each of platens 414a, 414b, 414c, and 414d can have up to two polishing heads (not shown). Platens 414a, 414b, 414c, and 414d can be configured to perform a CMP process on the wafers. Each platen can have a corresponding loading/un-loading stage. Platens 414a, 414b, 414c, and 414d can be part of a CMP system similar to CMP system 100 illustrated in FIG. 1. For example, platens 414a, 414b, 414c, and 414d can each have dispenser 110 fluidly connected to abrasive solution tank 120 and additive solution tank 122, polishing pad 106, and substrate carrier 104 communicatively connected to computer system 108. After the CMP process, the wafers can be transferred back to processing chamber 415 by the robot 415a. Processing chamber 415 on CMP tool 400 shown in FIG. 4D can include clean module 415b, which can perform pre-polishing and post-polishing operations. Pre-polishing operations can include, for example, a pre-clean. Post CMP processes can include, for example, a brush roller clean and/or IPA rinse and dry.

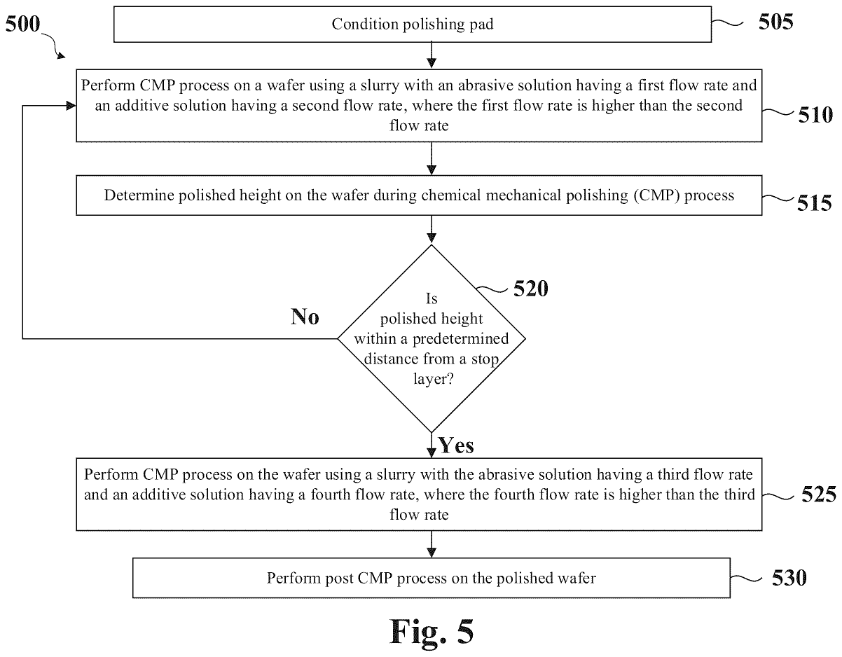

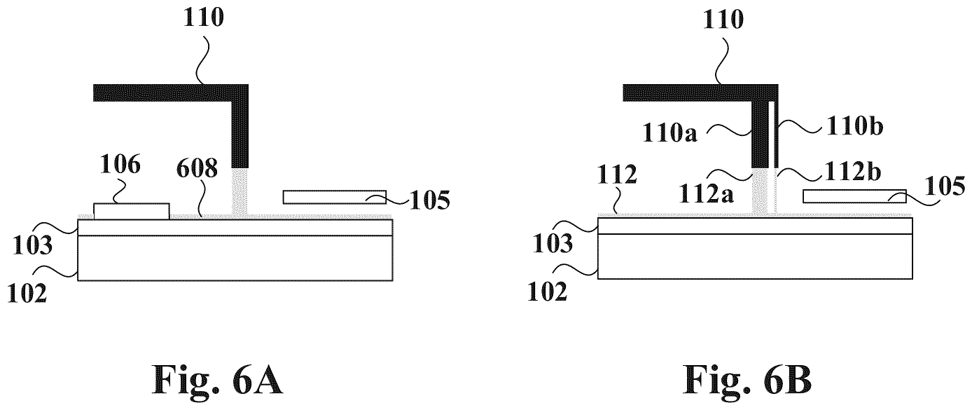

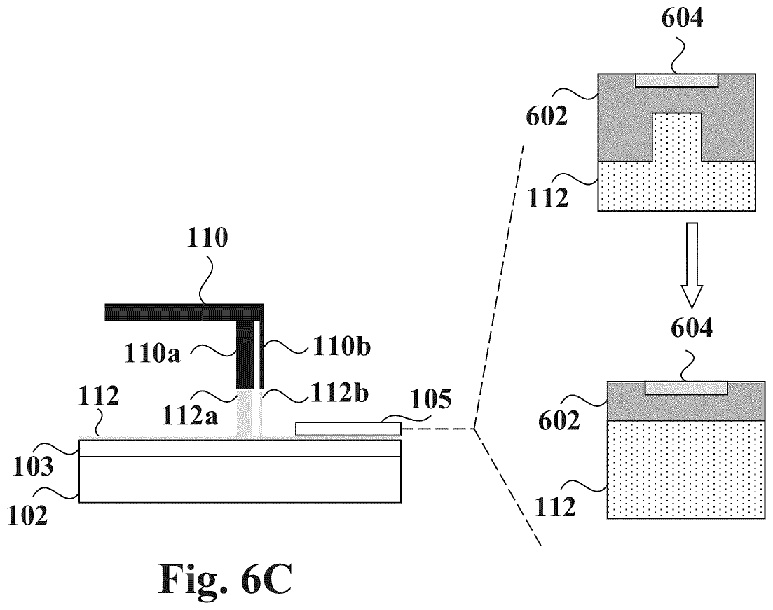

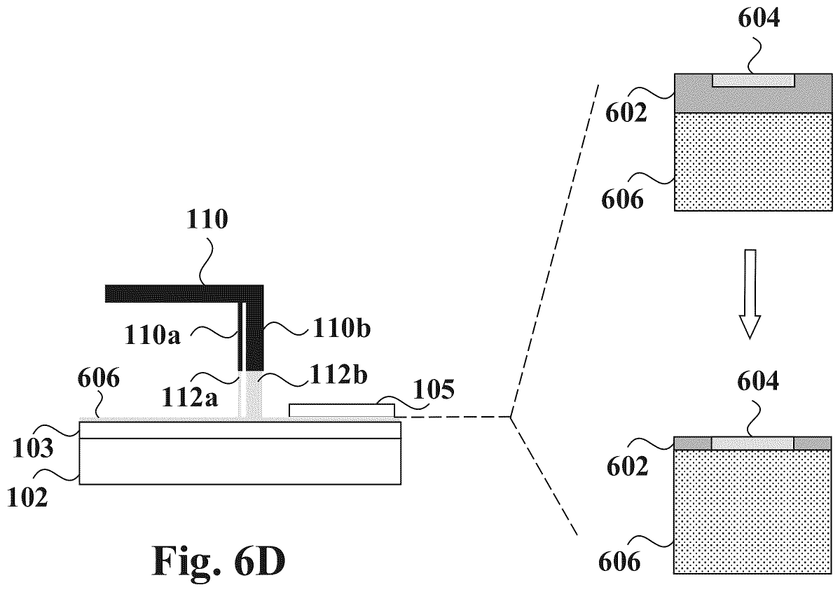

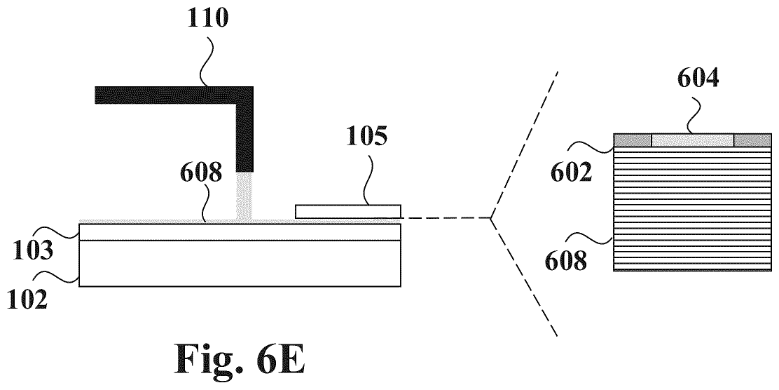

FIG. 5 is an exemplary method 500 for operating a polishing system such as CMP system 100, in accordance with some embodiments of the present disclosure. An example method 500 for performing a CMP process on a wafer is shown in FIGS. 6A-6E, according to some embodiments. For illustrative purposes, the operations illustrated in FIG. 5 will be described with reference to the example CMP process for polishing wafer 105 as illustrated in FIGS. 6A-6E. According to some embodiments, method 500 can include (a) a polishing pad conditioning stage, (b) a planarization stage of the CMP process, (c) a selective polishing stage, and (d) a post CMP cleaning process. Operations shown in the exemplary method 500 are not exhaustive; other operations can be performed before, after, or between any of the illustrated operations. In some embodiments, operations of the exemplary method 500 can be performed in a different order. Variations of the exemplary method 500 are within the scope of the present disclosure.

Exemplary method 500 begins with operation 505 which involves conditioning the polishing pad using a conditioning disk. A surface of the polishing pad has a texture with pores that help transport the slurry to the surface during polishing. With usage, the pores on the polishing pad can become clogged which can reduce the polishing ability of the pad. Referring to FIG. 6A, in some embodiments, during operation 505, conditioning disk 106 can be used to scratch the surface of polishing pad 103 to remove CMP by-products or slurry particles from the clogged pores to recover its performance. In some embodiments, while conditioning disk 106 conditions polishing pad 103, DI water 608 can be dispensed onto polishing pad 103 through dispenser 110. Conditioning disk 106 can absorb the DI water which can change the coefficient of friction and a hardness of its surface. In some embodiments, during operation 505, wafer 105 may not be lowered to form a contact with polishing pad 103.

Referring to FIG. 5, exemplary method 500 proceeds to operation 510, where a CMP process is performed on a wafer using a slurry. Since the first operation of the CMP process is the planarizing stage to physically planarize a bulk portion of the exposed material layer (also referred to herein as “targeted layer”) on the wafer, the slurry relies more on the abrasive solution to polish the material layer. With reference to FIG. 6B, during operation 510, abrasive solution 112a with a first flow rate can be dispensed through nozzle 110a onto polishing pad 103. Simultaneously, additive solution 112b with a second flow rate (which is less than the first flow rate) can be dispensed through nozzle 110b onto polishing pad 103. Abrasive solution 112a and additive solution 112b blend on polishing pad 103 to form slurry 112. Wafer 105 can be lowered to form a contact with polishing pad 103 as shown in FIG. 6C. Slurry 112 polishes a bulk of material layer on wafer 105. As shown in the inset of FIG. 6C, slurry 112 contacts a targeted layer 602, which has a stepped profile. Slurry 112 planarizes material layer 602 until a top surface of material layer 602 is within a predetermined distance from stop layer 604, where the predetermined distance can be between about 5 nm and about 35 nm.

Referring to FIG. 5, during operation 515, polishing characteristics associated with the CMP process can be determined using detection device 128. For example, polishing characteristics which can be a polished height of the targeted layer can be determined. Polishing characteristics associated with the polishing process can also include one or more of a polishing rate, a surface roughness, a surface uniformity, a surface contour, a surface dishing, and a surface defect density of a target substrate. Detection device 128 can be configured to measure one or more of an optical reflection, an optical refraction, an optical scattering, an electrical voltage, and an electrical current associated with the polishing process. In some embodiments, detection device 128 can be an electrode structure configured to measure an electrical current, electrical voltage, or platen torque from wafer 105 associated with the polished film's thickness or material composition of the exposed layer during the polishing process. In some embodiments, the polishing characteristic can be determined by an external detection device. For example, a surface roughness and/or dishing (e.g., a polishing characteristic) of the targeted layer on wafer 105 can be measured by a stand-alone atomic force microscopy (AFM) apparatus. By continuously determining and monitoring proximity of a stop layer from the top surface the exposed material layer on wafer 105, an end point of the planarization stage of the CMP process can be determined. The stop layer can be a material layer on wafer 105 at which the CMP process is required to stop or end. The stop layer can prevent over-polishing.

Referring to FIG. 5, during operation 520, polishing characteristics, such as a polished height of the targeted layer on wafer 105, can be monitored in real-time. A distance between the top surface of the exposed material layer and the stop layer on wafer 105 can be determined. If the stop layer is determined not be within a predetermined distance to the polished height of the targeted layer, the CMP process can continue to polish wafer 105 as described by the planarization stage in operation 510. If, on the other hand, the stop layer is determine to be within a predetermined distance from the top surface of the exposed material layer, the planarization stage can end and the CMP process can proceed to operation 525.

Referring to FIG. 5, during operation 525, the CMP process switches from a planarization stage to a selective polishing stage. During the selective polishing stage, the flow rate of the abrasive solution can be reduced to reduce the physical abrasion component of the CMP process. To make the CMP process more selective to the stop layer, the flow rate of the additive solution can be increased. The total flow rate in the selective polish stage can be the same as the total flow rate during the planarization stage. With reference to FIG. 6D, for example, the flow rate of abrasive solution 112a can be reduced from the first flow rate to a third flow rate and the flow rate of additive solution 112b can be increased from the second flow rate to a fourth flow rate. Abrasive solution 112a and additive solution 112b can blend to form slurry 606. The reduction in the flow rate of the abrasive solution and an increase in the flow rate of the additive solution, the additive solution chemically reacts with the targeted layer to form by-products on the wafer and abrasive solution assists in physically removing the by-products from the wafer surface. The additive solution selectively removes the targeted layer and does not chemically react with the stop layer. Upon exposure of the stop layer, the selective polishing operation ends. For example, as shown in the inset of FIG. 6D, slurry 606 can polish targeted layer 602 until stop layer 604 is exposed.

Referring to FIG. 5, during operation 530, by-products left on the wafer surface from the CMP process are removed. For example, surface of wafer 105 can be cleaned using roller brushes (not shown). Roller brushes can remove slurry particles, particles of the abraded targeted layer 602, and by-products of chemical reaction between additive solution 112b and targeted layer 602 from the polished wafer surface. In some embodiments, DI water can be dispensed onto the polished wafer surface during the roller brush cleaning process. In some embodiments, the polished surface can be cleaned by a DI water rinse. As shown in FIG. 6E, DI water 608 can be dispensed onto the polished wafer through dispenser 110. In some embodiments, the polished wafer surface can be cleaned using a silica slurry. In some embodiments, the silica slurry can include quaternary ammonium salts to provide a higher polish rate for silicon compared to silicon oxide. In some embodiments, the wafer can be cleaned with DI water or cleaning solutions that contain water-soluble polymers. These water-soluble polymers can be wetting agents.

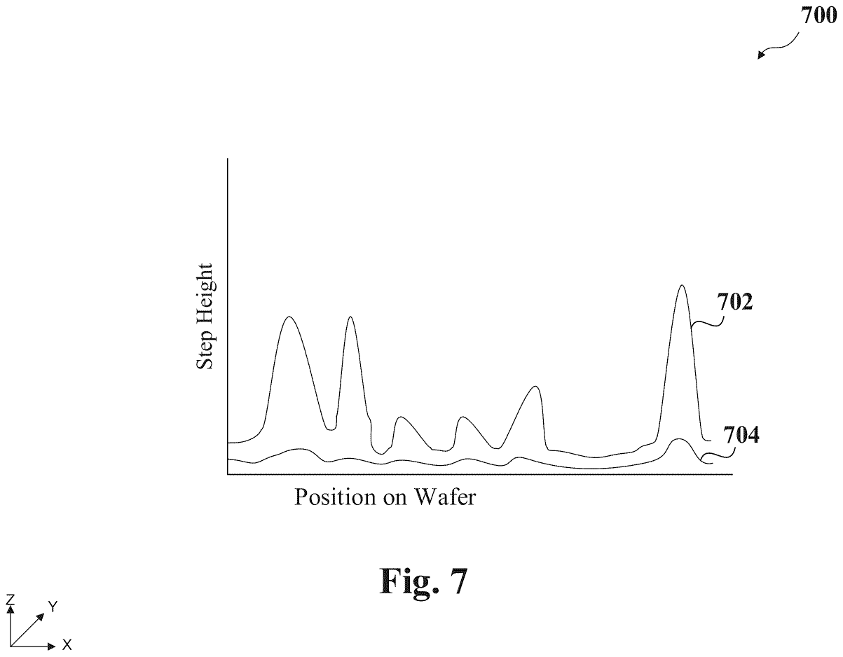

FIG. 7 illustrates polishing rate data 700 collected by detection device 128, according to some embodiments. A horizontal and a vertical axis of polishing rate data 700 represent a local portion (e.g., an edge portion or a central portion) of substrate 105 and a corresponding optical or electrical signal associated with a film profile (e.g., a film thickness or a surface contour) at the local portion of substrate 105, respectively. Signals 702 and 704 are measured optical or electrical signals at two different measurement times. Based on a vertical separation between signal 702 and 704, a respective polishing rate can be inferred. In some embodiments, signal 702 or 704 can itself be associated with one or more of a surface roughness, a height of the exposed material layer above an underlying layer, a surface uniformity, and surface dishing of substrate 105 at the respective measurement time.

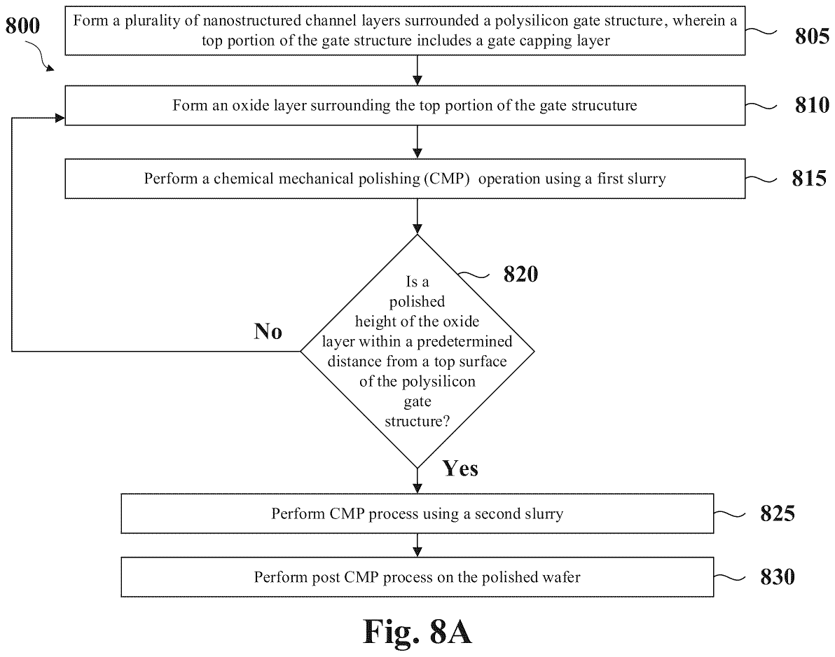

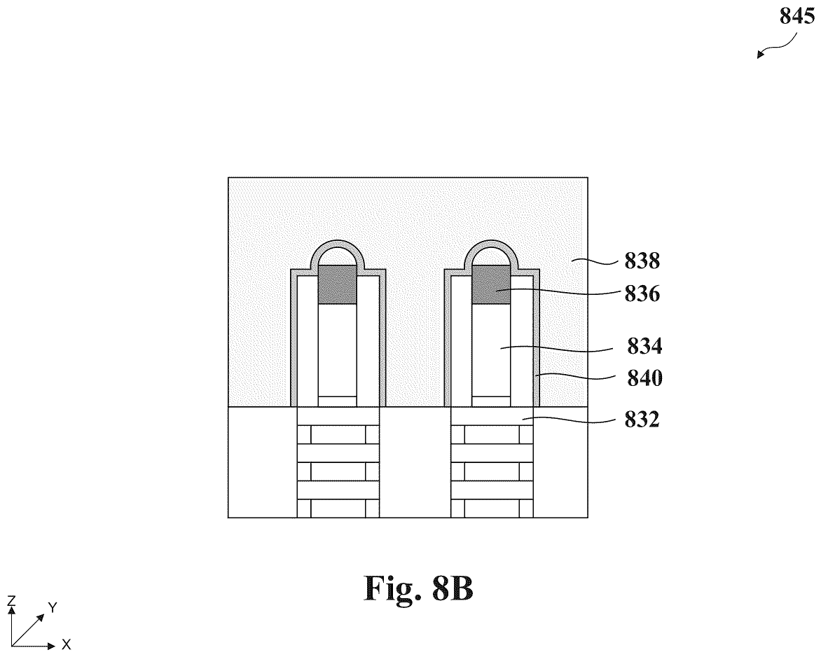

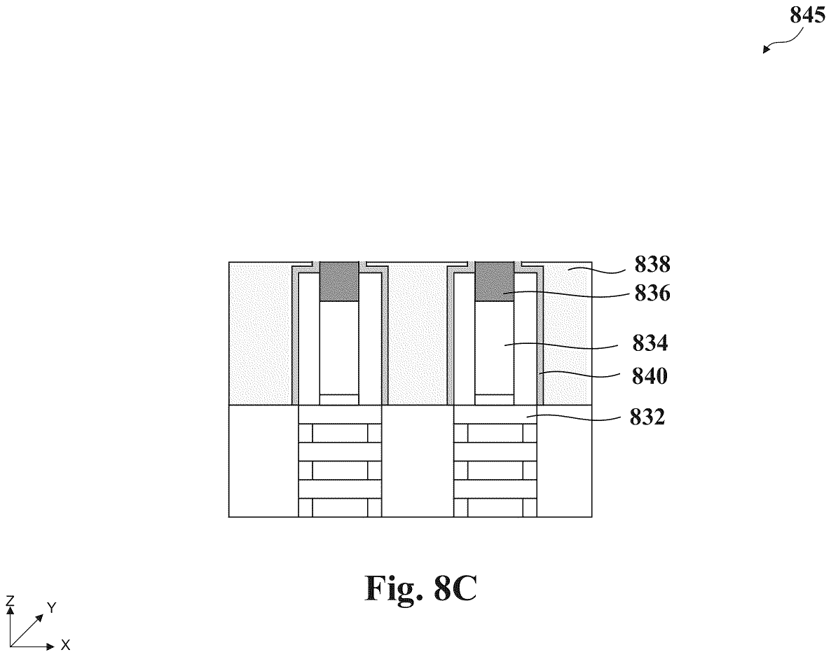

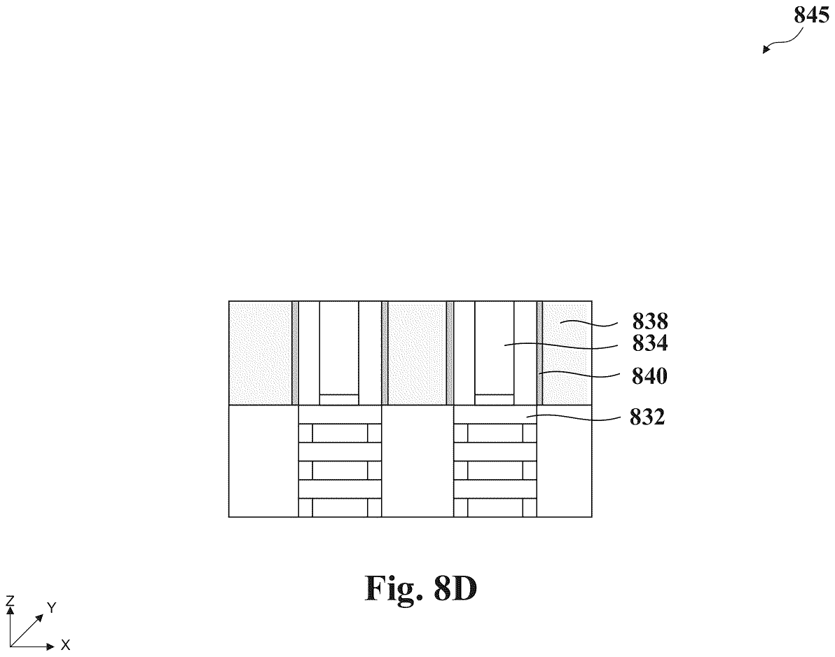

FIG. 8A is an exemplary method for polishing an oxide layer on a partially-fabricated substrate, in accordance with some embodiments of the present disclosure. Method 800 performs operations similar to those included in method 500, and can be performed by a polishing apparatus similar to CMP system 100 illustrated in FIG. 1. FIGS. 8B-8D show cross-sectional views of a partially-fabricated wafer undergoing a CMP process as outlined in method 800. Operations shown in the exemplary method 800 are not exhaustive; other operations can be performed before, after, or between any of the illustrated operations. In some embodiments, operations of the exemplary method 800 can be performed in a different order. Variations of the exemplary method 800 are within the scope of the present disclosure.

Referring to FIG. 8A, method 800 begins with operation 805 in which a partially-fabricated substrate as shown in FIG. 8B can be formed. FIG. 8B shows partially-fabricated substrate 845 which includes nanostructured channel layers 832 surrounded by polysilicon gate structure 1134 and etch stop layer 840. Oxide layer 838 is formed on top of and surrounding polysilicon gate structure 834. Gate capping layer 836 is disposed on top of polysilicon gate structure 834. According to some embodiments, method 800 performs a CMP process to polish oxide layer 838, etch stop layer 840, gate capping layer 836, and stop at a top surface of polysilicon gate structure 834.

Referring to FIG. 8A, operation 815 can be performed on partially-fabricated substrate 845 formed in operations 805 and 810 using CMP system 100 shown in FIG. 1. In operation 815, an oxide planarization operation is performed on oxide layer 838. Oxide layer 838 can be planarized as illustrated in FIG. 6C. As shown in FIG. 6C, abrasive solution 112a with a first flow rate and additive solution 112b with a second flow rate can be dispensed through dispenser 110 on polishing pad 103. Abrasive solution 112a and additive solution 112b can blend on polishing pad 103 to form slurry 112. The first flow rate can be higher than the second flow rate. For example, abrasive solution formed of 112a can have a flow rate of about 200 ml/min and additive solution 112b can have a flow rate of about 50 ml/min. Partially-fabricated substrate shown in FIG. 8B can be attached to substrate carrier 104. Oxide layer 838 can be polished by slurry 112 to remove a top portion of oxide layer 838.

During the planarization operation, detection device 128 can (a) monitor a polishing characteristic, such as step height (height of targeted layer above an underlying layer) or polished height of oxide layer 838, as well as (b) determine a proximity of a top surface of oxide layer 838 to an underlying stop layer, which in this example could be a silicon layer forming polysilicon gate structure 834. For example, as shown in FIG. 8C, detection device 128 can detect a change in signal indicating silicon layer forming polysilicon gate structure 834 is within a predetermined distance from a top surface of oxide layer 838. The change in signal can be between about 20% and about 60% of an initial value. The detected signal can be communicated to computer system 108 to determine if silicon layer forming polysilicon gate structure 834 is within a predetermined distance from the top surface of oxide layer 838, where the predetermined distance can be between about 5 nm and about 35 nm.

In operation 820, if silicon layer forming polysilicon gate structure 834 is determined to be within the predetermined distance from the top surface of oxide layer 838, the planarization operation ends, and the method proceeds to operation 825. If, on the other hand, the silicon layer forming polysilicon gate structure 834 is determined not be within the predetermined distance from the top surface of oxide layer 838, oxide layer 838 continues to be polished using slurry 112. At the end of the planarization stage, the partially-fabricated wafer is illustrated in FIG. 8C.

Referring to FIG. 8A, during operation 825, a selective polishing operation selectively removes the oxide layer and stops at the stop layer, which is the silicon layer forming the polysilicon gate structure. In operation 825, a selective polishing operation is performed on oxide layer 838 of FIG. 8C. Oxide layer 838 can be selectively polished as illustrated in FIG. 6D. As shown in FIG. 6D, abrasive solution 112a with a third flow rate and additive solution 112b with a fourth flow rate can be dispensed through dispenser 110 on polishing pad 103. Abrasive solution 112a and additive solution 112b can blend on polishing pad 103 to form slurry 606. The fourth flow rate can be higher than the third flow rate. For example, abrasive solution formed of 112a can have a flow rate of about 75 ml/min and additive solution 112b can have a flow rate of about about 175 ml/min. Partially-fabricated substrate shown in FIG. 8C can be attached to substrate carrier 104. Oxide layer 838, gate capping layer 836, and any other suitable material layer above a top surface of polysilicon gate structure 834 can be polished by slurry 606. The higher flow rate of additive solution 112b and a lower flow rate of the abrasive solution 112a contributes to a selective polishing operation that stops at the silicon layer forming the polysilicon gate structure 834, as shown in FIG. 8D.

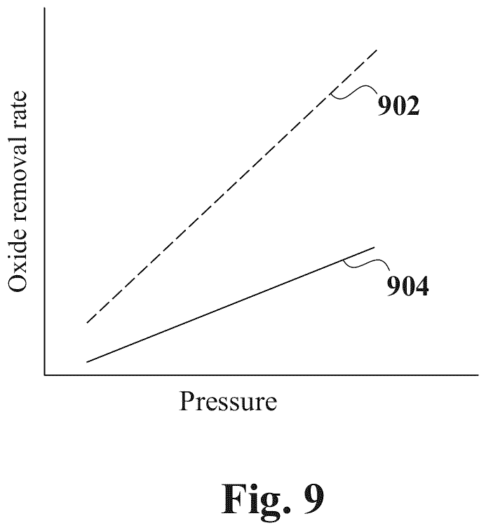

In some embodiments, the planarization operation and the selective polish operation can use abrasive solutions with different concentrations of the abrasive component. Compared to the selective polishing operation, the planarization operation predominantly relies on the abrasive solution to polish the oxide layer and therefore can use a higher concentration of the abrasive component in the abrasive solution. For example, the concentration of the abrasive component in the abrasive solution 112a dispensed during the planarization of oxide layer 838 can be about 0.08% by weight. As shown in FIG. 9, the removal rate of oxide layer 838 using a slurry including an about 0.08% by weight of abrasive component in abrasive solution 112a can be represented by curve 902. During the selective polishing operation, the abrasive or mechanical component of the CMP process is reduced to polish the remaining oxide layer 838 and have the CMP process stop at the silicon layer forming polysilicon gate structure 834. For example, the concentration of the abrasive component in the abrasive solution can be reduced to about 0.03% by weight. As shown in FIG. 9, the removal rate of oxide layer 838 using a slurry including an about 0.03% weight of abrasive component in abrasive solution 112a can be represented by curve 904.

In some embodiments, the removal rate increases with downward pressure or force applied on wafer 105. For example, as shown in FIG. 9, the removal rate of an oxide layer and a silicon nitride (SiN) layer increases linearly with pressure.

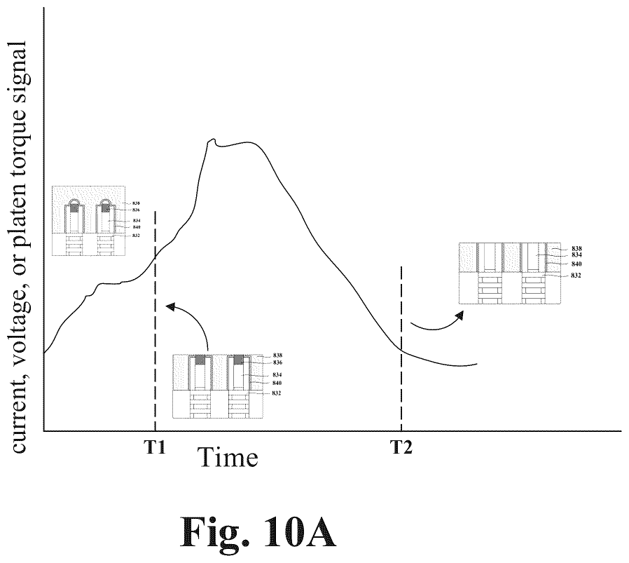

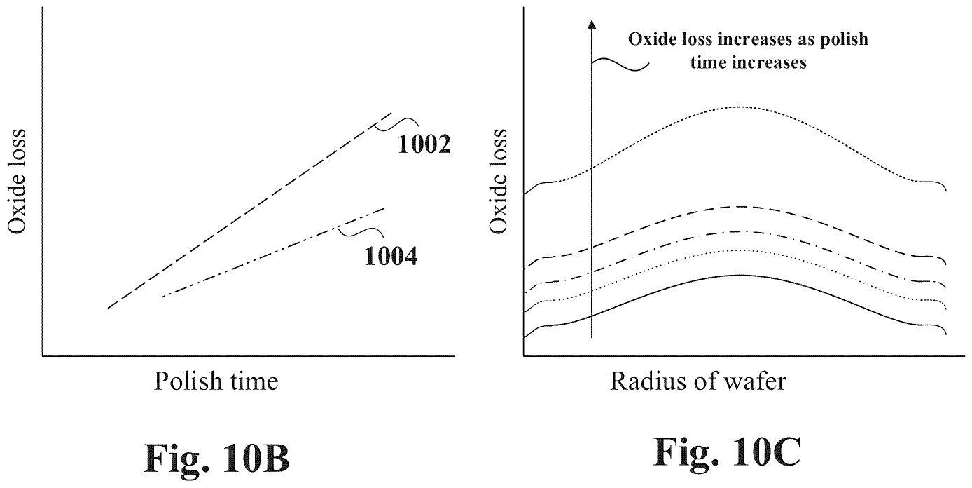

In some embodiments, the detection device and the computer system can provide end point control. End point control can (a) determine an end of the planarizing stage and (b) implement switching from the planarizing stage to the selective polishing stage. For example, with reference to FIG. 10A, detection device 128 can monitor a current, voltage, or platen torque signal deterministic of a composition of the exposed material layer on partially-fabricated substrate 845. The above signals can be communicated to computer system 108, which can control the concentration of abrasive component in abrasive solution 112a. The change the abrasive component concentration from about 0.08% Ce(OH)₄ to about 0.03% Ce(OH)₄ in abrasive solution 112a Until time T1, an upper portion of oxide layer 838 can be polished using slurry 112 with abrasive solution 112a using about 0.08% by weight of abrasive component, according to some embodiments. Around time T1, the current, voltage, or platen torque signal increases because of a change in material composition of the exposed material layer. The change in the current, voltage, or platen torque signal can be between about 20% and about 60% of a value prior to time T1. For example, the exposed material layer changes from oxide layer 838 to etch stop layer 840 and then to gate capping layer 836. At time T1, the planarization stage ends and the selective polishing stage begins. At time T1, the abrasive solution switches to using about 0.03% by weight of abrasive component, according to some embodiments. The selective polishing stage between time T1 and T2 uses slurry 112 with abrasive solution 112a with about 0.03% by weight of abrasive component, according to some embodiments. At time T2, polysilicon structure 834 is exposed and the selective polishing stage ends. The abrasive component concentration in slurry 112 can be changed by changing the flow rate of abrasive solution 112a and/or additive solution 112b, while keeping the total flow rate the same. In some embodiments, the abrasive component concentration in slurry 112 can be changed, for example, from 0.08% to 0.03% by reducing the flow rate of abrasive solution 112a and increasing the flow rate of additive solution 112b, while keeping the total flow rate of abrasive solution 112a and additive solution substantially constant.

Higher abrasive component accelerates the mechanical abrasion of the exposed material layer. For example, as shown in FIGS. 10B and 10C, an abrasive solution with the abrasive component concentration of about 0.08% by weight, as represented by curve 1002, can have a higher oxide removal rate compared to an abrasive solution with an abrasive solution with the abrasive component concentration of about 0.03% by weight, as represented by curve 1004. As shown in FIG. 10C, with increasing polish time using the slurry with an abrasive solution with an about 0.03% by weight of abrasive component, a thickness profile of oxide layer 838 across the substrate diameter does not change. Rather, the suppression of agglomeration to prevent formation of large clusters of particles of the abrasive component can prevent a higher oxide removal rate on the edge of the wafer compared to the wafer center, as shown in FIG. 10C.

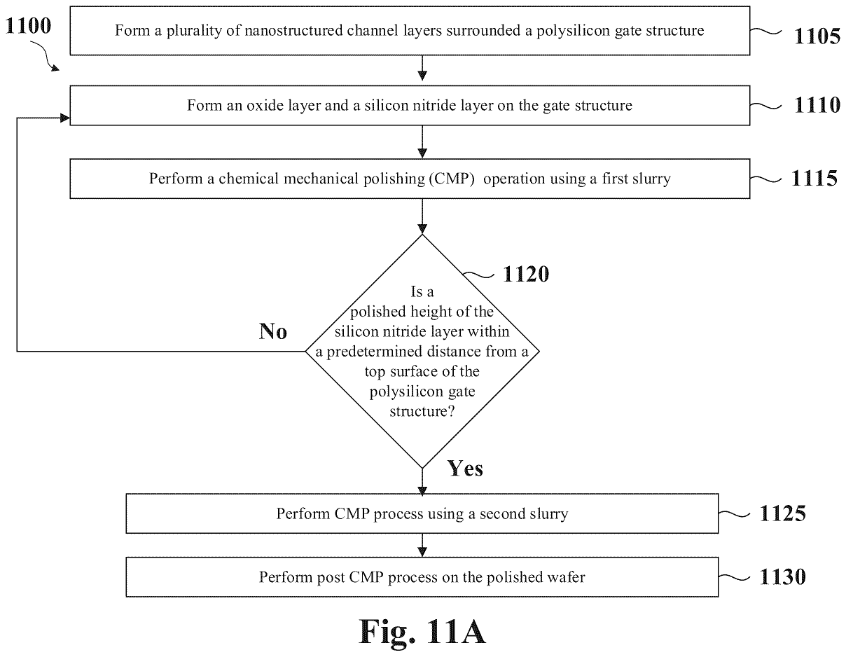

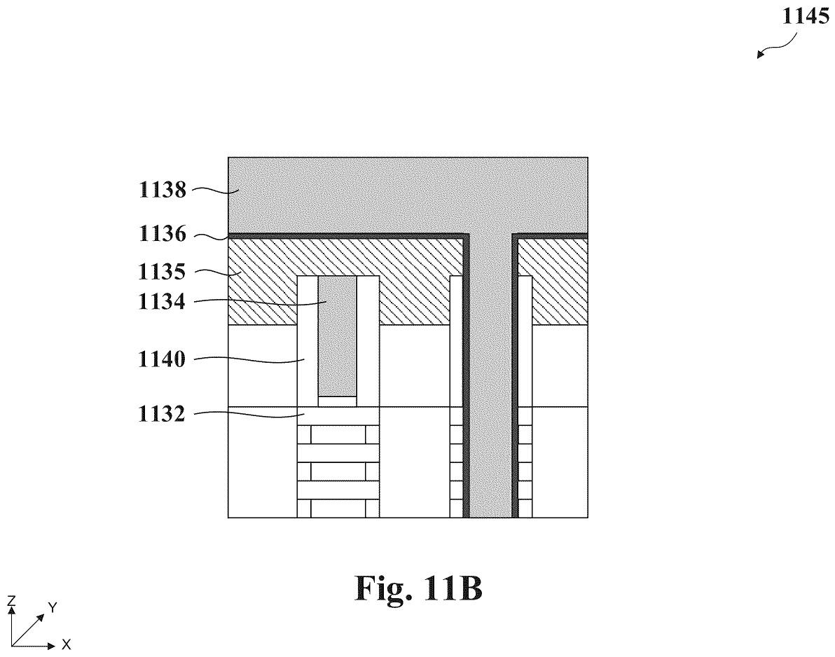

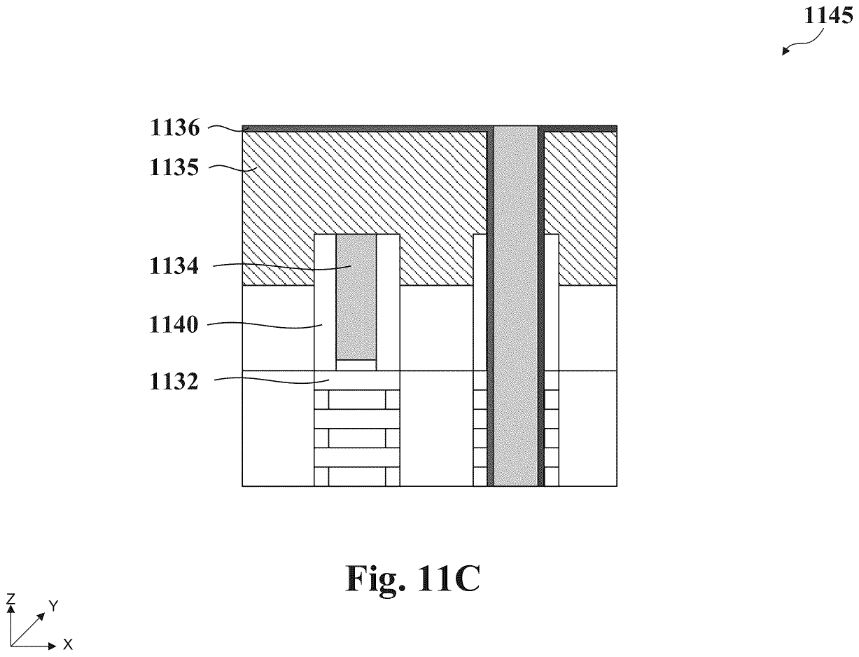

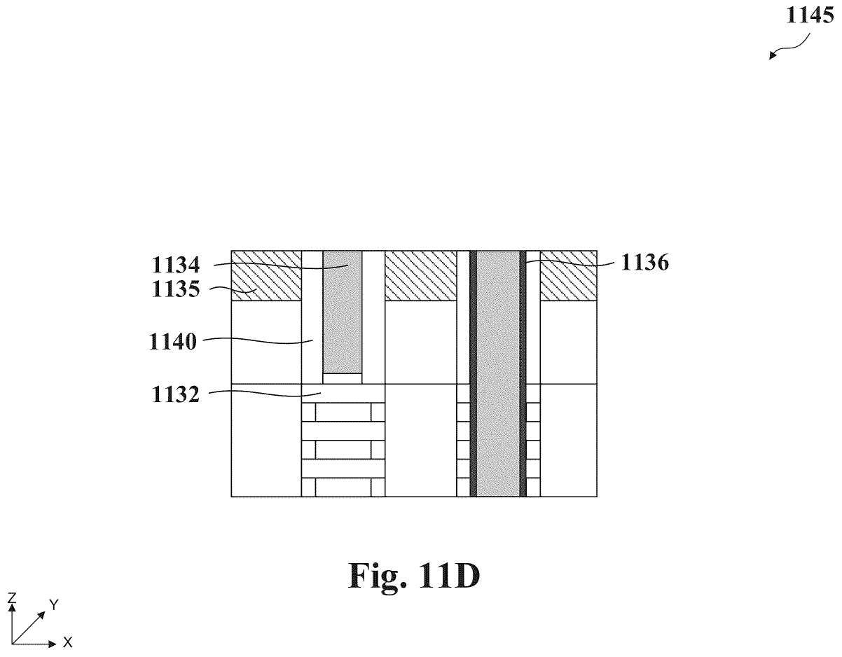

FIG. 11A is an exemplary method for polishing a silicon nitride (SiN) layer on a partially-fabricated substrate, in accordance with some embodiments of the present disclosure. Method 1100 performs operations similar to those included in method 500, and can be performed by a polishing apparatus similar to CMP system 100 illustrated in FIG. 1. FIGS. 11B-11D show cross-sectional views of a partially-fabricated wafer undergoing a CMP process as outlined by method 1100. Partially-fabricated substrate 1145 includes nanostructured channel layers 1132 surrounded by polysilicon gate structure 1134. First SiN layer 1135, oxide layer 1136, and second SiN layer 1138 are formed on top of polysilicon gate structure 1134. According to some embodiments, method 1100 performs a CMP process to polish second SiN layer 1138, oxide layer 1136, and first SiN layer 1135, and stop at a top surface of polysilicon gate structure 1134. Operations shown in the exemplary method 1100 are not exhaustive; other operations can be performed before, after, or between any of the illustrated operations. In some embodiments, operations of the exemplary method 1100 can be performed in a different order. Variations of the exemplary method 800 are within the scope of the present disclosure.

Referring to FIG. 11A, method 1100 begins with operation 1105 in which partially-fabricated substrate 1145 as shown in FIG. 11B can be formed. As shown in FIG. 11B, nanostructured channel layers 1132 surrounded by a polysilicon gate structure 1134 can be formed. In operation 1110, first SiN layer 1135, oxide layer 1136 and second SiN layer 1138 can be formed on top of polysilicon gate structure 1134.

Referring to FIG. 11A, operation 1115 can be performed by CMP system 100 shown in FIG. 1. In operation 1115, a planarization operation is performed on second SiN layer 1138. Second SiN layer 1138 can be planarized as illustrated in FIG. 6C. As shown in FIG. 6C, abrasive solution 112a with a first flow rate and additive solution 112b with a second flow rate can be dispensed through dispenser 110 on polishing pad 103. Abrasive solution 112a and additive solution 112b can blend on polishing pad 103 to form slurry 112. The first flow rate can be higher than the second flow rate. For example, abrasive solution formed of 112a can have a flow rate of about 200 ml/min and additive solution 112b can have a flow rate of about 50 ml/min. Partially-fabricated substrate shown in FIG. 11B can be attached to substrate carrier 104. Second SiN layer 1138 can be polished by slurry 112 until (a) oxide layer 1136 is exposed or (b) a top surface of second SiN layer 1138 is within a predetermined distance from a top surface of polysilicon gate structure 1134, where the predetermined distance can be between about 5 nm to about 35 nm.

During the planarization operation, detection device 128 can (a) monitor a polishing characteristic such as step height or polished height of second SiN layer 1138 as well as (b) determine proximity of a top surface of second SiN layer 1138 to an underlying stop layer, which in this example could be a silicon layer forming polysilicon gate structure 1134. Detection device 128 can detect a change in the signal indicating silicon layer forming polysilicon gate structure 1134 in close proximity to a top surface of second SiN layer 1138. The change can be between about −20% and about 20% of an initial value. The detected signal can be communicated to computer system 108 to determine if silicon layer forming polysilicon gate structure 1134 is within a predetermined distance from the top surface of second SiN layer 1138, where the predetermined distance can be between about 5 nm and about 35 nm.

In operation 1120, if a top surface of polysilicon gate structure 1134 is determined to be within the predetermined distance from the top surface of second SiN layer 1138, the planarization operation ends. If, on the other hand, the silicon layer forming polysilicon gate structure 1134 is determined not be within the predetermined distance from the top surface of second SiN layer 1138, second SiN layer 1138 continues to be polished using slurry 112. At the end of the planarization stage, the partially-fabricated wafer is illustrated in FIG. 11C

Referring to FIG. 11A, method 1100 can proceed to operation 1125 during which a selective polishing operation selectively removes the oxide layer and the first SiN layer and stops at the stop layer, which is the silicon layer forming the polysilicon gate structure. In operation 1125, a selective polishing operation is performed on oxide layer 1136 and first SiN layer 1135. Oxide layer 1136 and first SiN layer 1135 can be selectively polished as illustrated in FIG. 6D. As shown in FIG. 6D, abrasive solution 112a with a third flow rate and additive solution 112b with a fourth flow rate can be dispensed through dispenser 110 on polishing pad 103. Abrasive solution 112a and additive solution 112b can blend on polishing pad 103 to form slurry 606. The fourth flow rate can be higher than the third flow rate. For example, abrasive solution formed of 112a can have a flow rate of about 75 ml/min and additive solution 112b can have a flow rate of about 175 ml/min. Partially-fabricated substrate shown in FIG. 11C can be attached to substrate carrier 104. Oxide layer 1136, first SiN layer 1135, and any other suitable material layer above a top surface of polysilicon gate structure 1134 can be polished by slurry 606. The higher flow rate of additive solution 112b and a lower flow rate of the abrasive solution contributes to a selective polishing operation that stops at the silicon layer forming polysilicon gate structure 1134, as shown in FIG. 11D.

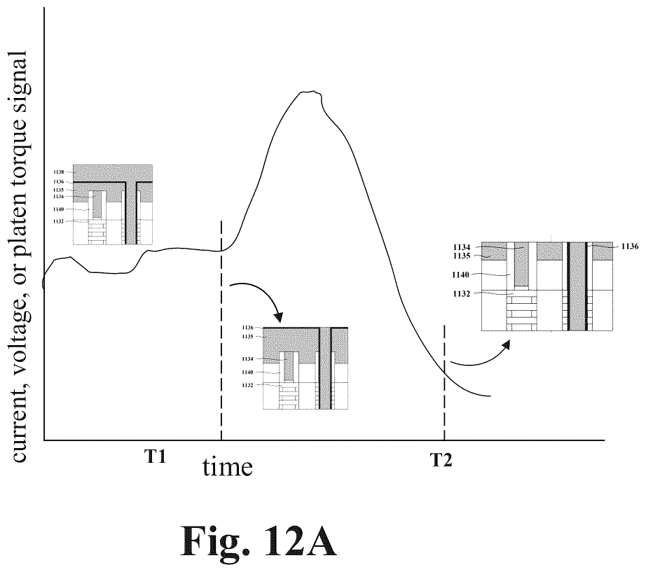

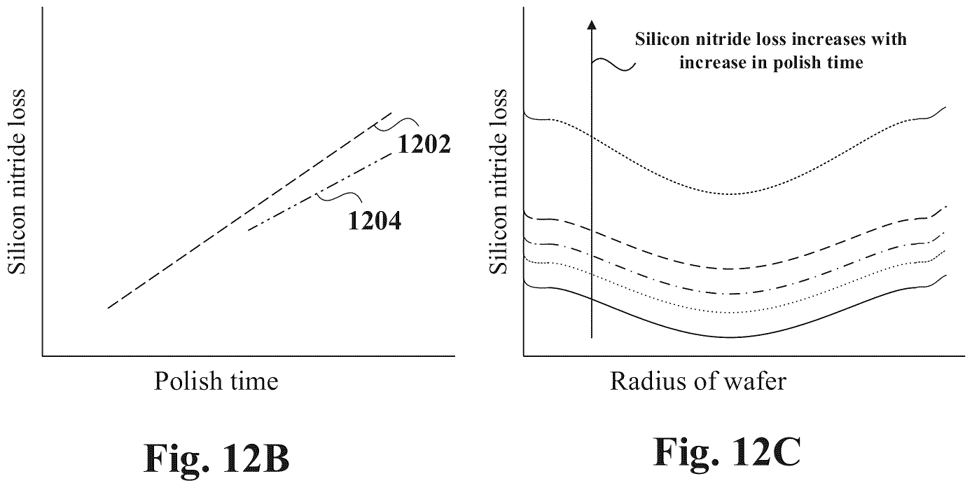

In some embodiments, the detection device and the computer system can provide end point control. End point control can (a) determine an end of the planarizing stage and (b) implement switching from the planarizing stage to the selective polishing stage. For example, with reference to FIG. 12A, detection device 128 can monitor a current, voltage, or platen torque signal deterministic of a composition of the exposed material layer on partially-fabricated substrate 1145. The above signals can be communicated to computer system 108, which can control the concentration of abrasive component in abrasive solution 112a. Until time T1, second SiN layer 1138 has been polished using slurry 112 with abrasive solution 112a with about 0.08% by weight of abrasive component. Around time T1, the current, voltage, or platen torque signal increases because of a change in material composition of the exposed material layer. The change in the current, voltage, or platen torque signal can be between about- 20% and about 20% of a value prior to time T1. For example, the exposed material layer changes from second SiN layer 1138 to oxide layer 1136. At time T1, the planarization stage ends and the selective polishing stage begins. At time T1, the abrasive solution can be switched to using about 0.03% by weight of abrasive component. The selective polishing stage between time T1 and T2 can use abrasive solution 112a with about 0.03% by weight of abrasive component. The abrasive component concentration in slurry 112 can be changed by changing the flow rate of abrasive solution 112a and/or additive solution 112b, while keeping the total flow rate the same. In some embodiments, the abrasive component concentration in slurry can be changed, for example, from 0.08% to 0.03% by reducing the flow rate of abrasive solution 112a and increasing the flow rate of additive solution 112b, while keeping the total flow rate of abrasive solution 112a and additive solution constant. At time T2, polysilicon structure 1134 is exposed and the selective polishing stage ends.

Compared to the selective polishing operation, the planarization operation predominantly relies on the abrasive solution to polish the oxide layer and therefore can use a higher concentration of the abrasive component in the abrasive solution. For example, the concentration of the abrasive component in the abrasive solution 112a dispensed during the planarization of second SiN layer 1138 can be about 0.08% by weight of abrasive component. As shown in FIG. 12B, the removal rate of second SiN layer 1138 using a slurry with an abrasive solution with about 0.08% by weight abrasive component can be represented by curve 1202. To reduce the abrasive or mechanical component of the CMP process during the selective polishing operation to polish first SiN layer 1135 and have the CMP process stop at the polysilicon gate structure 1134, the concentration of the abrasive component in the abrasive solution can be reduced to about 0.03% by weight of abrasive component. As shown in FIG. 12B, the removal rate of SiN layer 1138 using a slurry with an abrasive solution including an about 0.03% by weight of abrasive component can be represented by curve 1204.

In some embodiments, the polish time decreases with an increase in the concentration of the abrasive component in the abrasive solution. Higher abrasive component accelerates the mechanical abrasion of the material layer. For example, as shown in FIG. 12B, an abrasive solution with the abrasive component concentration of about 0.08% by weight can have a higher oxide removal rate compared to an abrasive solution with an abrasive solution with the abrasive component concentration of about 0.03% weight. As shown in FIG. 12C, with increasing polish time using the slurry with an about 0.03% by weight of abrasive component, a thickness profile of second SiN layer 1138 does not change. Rather, the suppression of agglomeration to prevent formation of large clusters of particles of the abrasive component can prevent a higher SiN removal rate on the edge of the wafer compared to the wafer center, as shown in FIG. 12C.

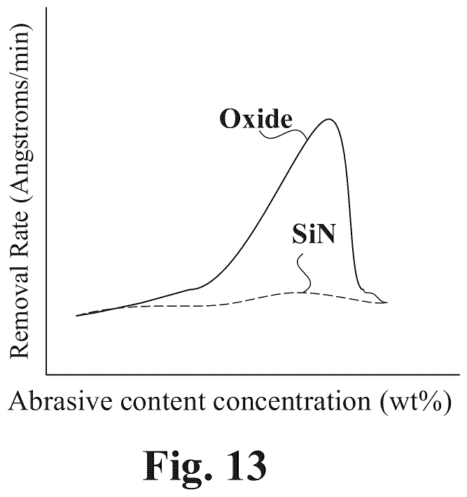

In some embodiments, a removal rate of a targeted layer does not increase indefinitely with increase in concentration of abrasive component in the abrasive solution forming the slurry. For example, as shown in FIG. 13, for lower concentrations of the abrasive component in the slurry, the removal rate of a SiN material layer and an oxide material layer increases linearly with increase on the concentration of abrasive component (% by weight) in the slurry. The removal rate of the SiN material layer and the oxide layer reach a peak. The removal rate for both SiN material layer and oxide material layer decreases for higher concentration of abrasive component in the slurry. In some embodiments, abrasive component Ce(OH)₄ is adsorbed on the oxide material layer to form a Ce—O—Si bond. The adsorbed abrasive component includes a positive charge. With an increase in concentration of abrasive component in the slurry, electrostatic repulsion increases between the adsorbed abrasive component on the oxide material layer and the abrasive component in the slurry. This can contribute to a decrease in the oxide material layer removal rate for higher concentration of abrasive component in the slurry, as shown in FIG. 13. A similar mechanism applies to the SiN material layer removal rate as well, as shown in FIG. 13.

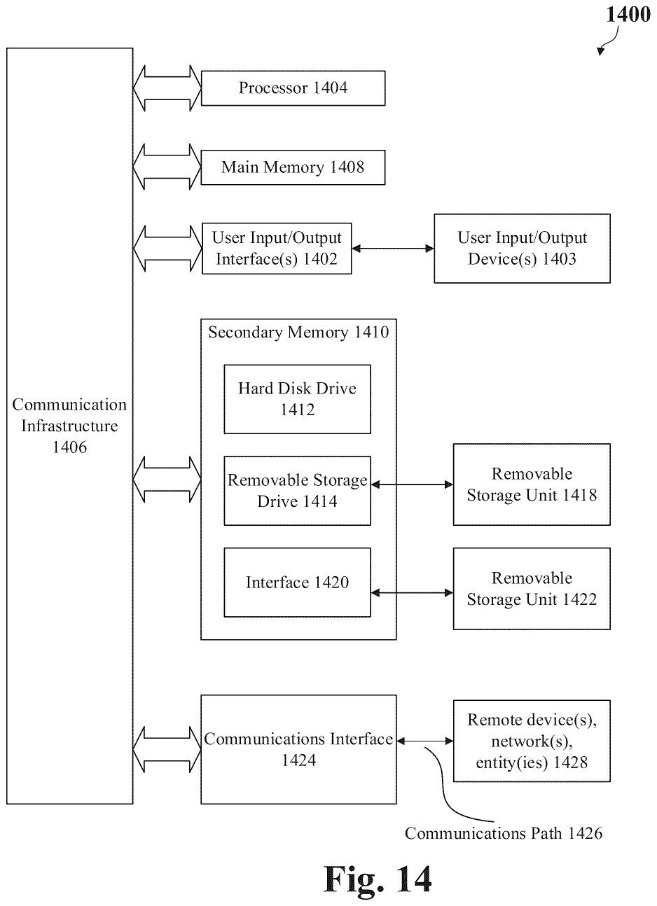

Various aspects of the exemplary embodiments may be implemented in software, firmware, hardware, or a combination thereof. FIG. 14 is an illustration of an example computer system 1400 in which embodiments of the present disclosure, or portions thereof, can be implemented as computer-readable code. Various embodiments of the present disclosure are described in terms of this example computer system 1400.

Computer system 1400 can be an example of computer system 108, and can include one or more processors, such as processor 1404. Processor 1404 is connected to a communication infrastructure 1406 (e.g., a bus or network).

Computer system 1400 also includes a main memory 1408, such as random access memory (RAM), and may also include a secondary memory 1410. Secondary memory 1410 can include, for example, a hard disk drive 1412, a removable storage drive 1414, and/or a memory stick. Removable storage drive 1414 can include a floppy disk drive, a magnetic tape drive, an optical disk drive, a flash memory, or the like. Removable storage drive 1414 reads from and/or writes to a removable storage unit 1418 in a well-known manner. Removable storage unit 1418 can include a floppy disk, magnetic tape, optical disk, and/or flash drive, which are read by and written to by removable storage drive 1414. Removable storage unit 818 includes a computer-readable storage medium having stored therein computer software and/or data. Computer system 1400 includes a display interface 1402 (which can include input and output devices 1403, such as keyboards and mice) that forwards graphics, text, and other data from communication infrastructure 1406 (or from a frame buffer not shown).

In alternative implementations, secondary memory 1410 can include other similar devices for allowing computer programs or other instructions to be loaded into computer system 1400 (e.g. loaded into main memory 1408). Such devices can include, for example, a removable storage unit 1422 and an interface 1420. Examples of such devices include a program cartridge and cartridge interface (such as those found in video game devices), a removable memory chip (e.g., EPROM or PROM) and associated socket, and other removable storage units 1422 and interfaces 1420 which allow software and data to be transferred from the removable storage unit 1422 to computer system 1400.

Computer system 1400 can also include a communications interface 1424. Communications interface 1424 allows software and data to be transferred between computer system 1400 and external devices. Communications interface 1424 can include a modem, a network interface (such as an Ethernet card), a communications port, or the like. Software and data transferred via communications interface 1424 are in the form of signals which may be electronic, electromagnetic, optical, or other signals capable of being received by communications interface 1424. These signals are provided to communications interface 1424 via a communications path 1426. Communications path 1426 carries signals and can be implemented using wire or cable, fiber optics, a phone line, a cellular phone link, a RF link, or other suitable communication channels.

In this document, the terms “computer program storage medium” and “computer-readable storage medium” are used to generally refer to non-transitory media such as removable storage unit 1418, removable storage unit 1422, and a hard disk installed in hard disk drive 1412. Computer program storage medium and computer-readable storage medium can also refer to memories, such as main memory 1408 and secondary memory 1410, which can be semiconductor memories (e.g., DRAMs). Embodiments of the present disclosure can employ any computer-readable medium, known now or in the future. Examples of computer-readable storage media include, but are not limited to, non-transitory primary storage devices (e.g., any type of random access memory), and non-transitory secondary storage devices (e.g., hard drives, floppy disks, CD ROMS, ZIP disks, tapes, magnetic storage devices, optical storage devices, MEMS, and nanotechnological storage devices).

These computer program products provide software to computer system 1400. Embodiments of the present disclosure are also directed to computer program products including software stored on any computer-readable storage medium. Such software, when executed in one or more data processing devices, causes a data processing device(s) to operate as described herein.

Computer programs (also referred to herein as “computer control logic”) are stored in main memory 1408 and/or secondary memory 1410. Computer programs may also be received via communications interface 1424. Such computer programs, when executed, enable computer system 1400 to implement various embodiments of the present disclosure. In particular, the computer programs, when executed, enable processor 1404 to implement processes of embodiments of the present disclosure, such as the operations in method 500 illustrated by FIG. 5, method 800 illustrated by FIG. 8A, and method 1100 illustrated by FIG. 11A. Where embodiments of the present disclosure are implemented using software, the software can be stored in a computer program product and loaded into computer system 1400 using removable storage drive 1414, interface 1420, hard drive 1412, or communications interface 1424.

The functions/operations in the preceding embodiments can be implemented in a wide variety of configurations and architectures. Therefore, some or all of the operations in the preceding embodiments—e.g., functions of polishing system 100 described in FIG. 1, functions of polishing system 100 described in FIGS. 6A-6E, method 500 illustrated by FIG. 5, method 800 illustrated by FIG. 8A, and method 1100 described in FIG. 11A—can be performed in computer system 1400 (e.g. by processor 1404), in hardware, in software or in combination thereof. In some embodiments, a tangible apparatus or article of manufacture including a tangible computer useable or readable medium having control logic (software) stored thereon is also referred to herein as a computer program product or program storage device. This includes, but is not limited to, computer system 1400, main memory 1408, secondary memory 1410 and removable storage units 1418 and 1422, as well as tangible articles of manufacture embodying any combination of the foregoing. Such control logic, when executed by one or more data processing devices (such as computer system 1400), causes such data processing devices to operate as described herein. For example, the hardware/equipment can be connected to or be part of element 1428 (remote device(s), network(s), entity(ies) 1428) of computer system 1400.

The present disclosure provides CMP system 100 and method 500 in which the slurry performance depending on a mixing ratio of abrasive solution 112a and additive solution 112b can be optimized by controlling flow rates of the abrasive and additive solutions 112a and 112b. In the disclosed CMP system 100 and method 500, abrasive solution 112a and the additive solution 112b are dispensed on polishing pad 103 through two separate nozzles 110a and 110b and mixed on polishing pad 103 to form the slurry. The concentration or mixing ratio of abrasive solution 112a and additive solution 112b can be adapted even though a total flow rate can remain substantially constant. A benefit of the present disclosure is that CMP system 100 and method 500 that provide an optimized CMP process using a single platen 102 and a single abrasive solution to CMP different dielectric layers. An optimized CMP process refers to a CMP process that can be modified to be effective for (a) a planarization operation that is a physically abrasive polishing process, as well as for (b) a selective polishing operation that is a chemical process in which the additive solution being a chemically reactive component selectively reacts with the material layer and the abrasive component mechanically removes the material layer. During the planarization operation, the material layer can be predominantly removed by physical abrasion. On the other hand, during the selective polishing operation, the material layer can be predominantly removed by a chemical reaction.

In some embodiments, a method includes blending an abrasive solution and an additive solution to form a slurry on a rotating polishing pad, contacting a substrate with the slurry on the polishing pad, where the substrate is held and rotated by a substrate carrier, and polishing an exposed layer on the substrate using the slurry. In some embodiments, the polishing can include monitoring a current, voltage, or torque measurement representing a material composition of the exposed layer, determining a change in the current, voltage, or torque measurement due to a change in the material composition of the exposed layer, and changing a first flow rate of the abrasive solution and a second flow rate of the additive solution based on the change in the signal. In some embodiments, the substrate can be cleaned after polishing.

In some embodiments, a polishing method includes chemical mechanical polishing a material layer on a substrate using a first slurry formed of an abrasive solution and an additive solution and determining a polished height of the material layer. In some embodiments, in response to the polished height being within a predetermined distance from a stop layer on the substrate, the method can include switching from the first slurry to a second slurry formed of the abrasive solution and the additive solution, where the second slurry provides a higher material selectivity than the first slurry, and chemical mechanical polishing the material layer using the second slurry.

In some embodiments, a polishing system includes a polishing pad configured to rotate on a platen, and a carrier configured to hold a substrate over the polishing pad and in contact with the polishing pad. In some embodiments, the polishing system further include a dispenser, including a first nozzle configured to dispense an abrasive solution on the polishing pad, and a second nozzle configured to dispense an additive solution on the polishing pad to blend with the abrasive solution to form a slurry.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
blending an abrasive solution and an additive solution to form a slurry on a rotating polishing pad;
contacting a substrate with the slurry on the polishing pad, wherein the substrate is held and rotated by a substrate carrier;
polishing an exposed layer on the substrate using the slurry, the polishing comprising:
monitoring a current, voltage, or torque measurement representing a material composition of the exposed layer;
determining a change in the current, voltage, or torque measurement due to a change in the material composition of the exposed layer; and
changing a first flow rate of the abrasive solution and a second flow rate of the additive solution based on the change in the current, voltage, or torque measurement; and
cleaning the substrate after polishing.

2. The method of claim 1, further comprising diluting an abrasive component in de-ionized (DI) water to form the abrasive solution.

3. The method of claim 1, further comprising diluting an additive component in de-ionized (DI) water to form the additive solution.

4. The method of claim 1, wherein the blending comprises forming the slurry with a pH between about 4.0 and about 5.0.

5. The method of claim 2, further comprising changing a concentration of the abrasive component from a first concentration to a second concentration based on the change in the current, voltage, or torque measurement, wherein the first concentration is greater than the second concentration.

6. The method of claim 1, wherein changing the first flow rate of the abrasive solution comprises changing from the first flow rate to a third flow rate, wherein the third flow rate is less than the first flow rate.

7. The method of claim 6, wherein changing the second flow rate of the additive solution comprises changing the second flow rate to a fourth flow rate, wherein the second flow rate is less than the fourth flow rate.

8. The method of claim 7, further comprising maintaining a sum of the first and second flow rates substantially equal to a sum of the third and fourth flow rates.

9. The method of claim 1, wherein cleaning the substrate comprises scrubbing a top surface of the substrate with roller brushes.

10. A polishing method, comprising:
chemical mechanical polishing a material layer on a substrate using a first slurry formed of an abrasive solution and an additive solution;
determining a polished height of the material layer;
in response to the polished height being within a predetermined distance from a stop layer on the substrate, switching from the first slurry to a second slurry formed of the abrasive solution and the additive solution, wherein the second slurry provides a higher material selectivity than the first slurry;
chemical mechanical polishing the material layer using the second slurry.

11. The polishing method of claim 10, further comprising mixing the abrasive solution and the additive solution on a polishing pad to form the first slurry.

12. The polishing method of claim 10, further comprising dispensing the abrasive solution at a first flow rate and dispensing an additive solution at a second flow rate to form the first slurry, wherein the first flow rate is greater than the second flow rate.

13. The polishing method of claim 10, further comprising dispensing the abrasive solution at a third flow rate and the additive solution at a fourth flow rate to form the second slurry, wherein the fourth flow rate is greater than the third flow rate.

14. The polishing method of claim 10, wherein the first slurry comprises an abrasive component with a first concentration and the second slurry comprises the abrasive component with a second concentration, wherein the second concentration is less than the first concentration.

15. The polishing method of claim 10, wherein a pH of the first slurry and the second slurry is between about 4.0 and about 5.0.

16. The polishing method of claim 10, wherein determining the polished height comprises monitoring one or more of a current, a voltage, or a platen torque measurement.

17. The polishing method of claim 16, wherein switching from the first slurry to the second slurry is based on a change in at least one of the voltage, the current, or the platen torque measurement, wherein the change is between XX % and about YY % of an initial voltage, current or platen torque measurement.

18. A polishing system, comprising:
a polishing pad configured to rotate on a platen;
a carrier configured to hold a substrate over the polishing pad and in contact with the polishing pad; and
a dispenser, comprising:
a first nozzle configured to dispense an abrasive solution on the polishing pad; and
a second nozzle configured to dispense an additive solution on the polishing pad to blend with the abrasive solution to form a slurry.

19. The polishing system of claim 18, further comprising a detection device configured to measure a polished height of a material layer on the substrate.

20. The polishing system of claim 18, further comprising a controller configured to communicate with a computer system configured to control a first flow rate of the abrasive solution and a second flow rate of the additive solution.
